(19) United States
(12) Patent Application Publication
(10) Pub. No.: US 2002/0009862 A1
(43) Pub. Date: Jan. 24, 2002

(54) Method of treating a semiconductor wafer thermally and semiconductor wafer fabricated by the same

(76) Inventor: Young-Hee Mun, Gumi-shi (KR)

Correspondence Address: JACOBSON HOLMAN PLLC, 400 SEVENTH STREET N.W., SUITE 600, WASHINGTON, DC, 20004, US

(21) Appl. No.: 09/742,127

(22) Filed: Dec. 22, 2000

(30) Foreign Application Priority Data
Apr. 10, 2000 (KR) 2000-58101

(51) Int. Cl. H01L 21/322

(52) U.S. Cl. 438/471

(57) ABSTRACT

A method of treating a semiconductor wafer thermally and a semiconductor wafer fabricated thereby and, more particularly, a method of producing a wafer ideal for fabricating semiconductor devices thereon through thermal treatment. The method of removing defects contained in single crystalline semiconductor by treating the wafer thermally includes the steps of carrying out a first heat treatment on the wafer at a temperature equal to or higher than 1200° C., and carrying out a second heat treatment on the wafer at a temperature equal to or lower than 800° C. A semiconductor wafer which is fabricated from a single crystalline semiconductor in accordance with the present invention is characterized in that the wafer is produced from a single crystalline semiconductor ingot which is formed by removing an OiSF ring by means of moving the OiSF ring from a center of a single crystalline semiconductor growth axis to a circumference and by extending a first area and a second area in which delta (Oi), as oxygen concentration difference between initial oxygen concentration and oxygen concentration after heat treatment in N₂ ambience at 1000° C. for 64 hours, is more greatly increased than other areas; that grown-in defects are removed from the wafer by heat treatment; that bulk micro-defects are formed in the wafer; and that a defect-free layer is formed from a surface of the wafer to a predetermined depth.

### BACKGROUND OF THE INVENTION

1. Field of the Invention

The present invention relates to a method of treating a semiconductor wafer thermally and a semiconductor wafer fabricated thereby and more particularly, to a method of producing a wafer ideal for fabricating semiconductor devices thereon through thermal treatment.

2. Discussion of Related Art

In general, silicon wafers are fabricated mainly by floating zone (Fz) or Czochralski (hereinafter abbreviated “Cz”) methods, with the Cz method is being more popular for silicon wafer fabrication.

Using the Cz method, a single crystalline silicon ingot is grown by placing polycrystalline silicon into a quartz crucible, melting the polycrystalline silicon down by heating with a graphite heater, dipping a seed crystal into the melt-down silicon to bring about crystallization at an interface therebetween, and pulling up the seed crystal while it is being rotated. The Cz method is characterized by the fact that 10¹⁷ to 10¹⁸ ea./cm³ oxygen atoms flow in as impurities during the growth of the crystal. Such oxygen impurity has a significant influence on mechanical strength, defect generation, and the like, of a resulting silicon wafer.

As the crystal grows from the melt-down silicon of a predetermined quantity in the quartz crucible, irregularity occurs due to non-uniformity of impurity distribution and thermal history difference in the axis direction of crystal growth owing to segregation. Such irregularity or non-uniformity has a great influence on the distribution of crystal defects in a single crystal. More particularly, vacancy, interstitial and mixed type defects depend on the pulling speed used during crystal growth and the temperature gradient ratio at the growing interface.

Due to the efforts of scientists, it has been learned that vacancy-rich type defects and interstitial-rich type defects exist in an inner area and an outer area relative to an Oxygen-induced Stacking Fault (OiSF) ring generated from general crystal growth conditions, respectively. As the OiSF ring has a great effect on the operation of semiconductor devices, studies have been undertaken to determine whether the OiSF ring is best removed by contracting it to the center of an ingot or by pushing it back to the circumference of the ingot when the crystal grows.

Unfortunately, these methods pose a new problem, namely that grown-in defect result when the crystal grows. It has been reported that single crystals without defects may be grown by removing the grown-in defects by means of adjusting the crystal pulling speed, V, and temperature gradient ratio, G, near a growing interface. This reported method of growing non-defective single crystals is as follows. When a structure of a hot zone existing inside a grower is fixed, the value, G, is determined as well. Next, a value of V/G depends on a variable, V. Thus, crystal defect distribution inside an ingot, size or defect, and density of defect depend on the value, V.

In order to eliminate an OiSF ring by contraction, the pulling speed of crystal growth is reduced, which is shown in FIG. 1. FIG. 1 shows an X-Ray Topography (XRT) image of a vertically cut single crystalline ingot which is grown by reducing a crystal pulling speed and treated thermally at a high temperature of about 1000° C. Although the result fails to show that the OiSF ring is contracted completely, it is possible to eliminate the OiSF ring completely by contracting it in the direction of a growth axis of the single crystalline ingot provided that the crystal pulling speed is reduced further. Thus, a non-defective single crystalline ingot may be provided by such method.

Unfortunately, however, it is difficult to control oxygen concentration by slowing down the crystal pulling speed, as well as to improve productivity of wafers by such method. Namely, there is a reduced ability to remove metal contaminants typically accompanied by the semiconductor fabrication due to the reduced productivity of wafer and the difficulty in controlling oxygen concentration.

Hence, the present wafer producing companies have developed individual methods of their own to remove the grown-in defects and enforce the gettering ability, i.e., the ability to remove metal contaminants. The removal of grown-in defects is achieved by a technique of silicon crystal growth, which is a combined technique of reducing crystal pulling speed and improving a hot zone structure to ameliorate the G value. When the gettering ability must be enforced, an external gettering method is introduced. That is, an external gettering method to which a process of wet blaster or poly-back seal is added is used, according to the species of semiconductor devices. In such instances, wafer contamination and the cost of producing a wafer rise due to a shock impacted on the wafer or the growth of a layer.

Thus, most of the wafer fabrication companies prefer the inner gettering method using oxygen concentration. Yet, the inner gettering method fails to remove defects such as metal impurity completely since the fabrication process introduces low temperature, high-energy ion implantation and ultra-micro critical dimension under 0.2 μm. Accordingly, the wafer fabrication companies are interested in producing an ideal wafer in which gettering ability is enforced by removing grown-in defects as well as forming nuclei in a wafer to provide Bulk Micro Defect (BMD) of high density.

When silicon crystal is grown in general, various bands appear according to crystal growth conditions. These bands are illustrated in FIG. 1.

FIG. 2 is a chart of oxygen concentration differences observed in a radial direction of a wafer through Fourier Transform Infrared (FTIR) spectrometer wherein the numbers are corresponding oxygen concentration by ppma (new ASTM base). In this case, the XRT results are attained by using the characteristics of different X-ray diffraction intensity according to the degree of oxygen precipitation.

Referring back to FIG. 1, there are various bands such as D, B, and C, wherein D indicates an OiSF ring, and the areas B and C have a great influence on device characteristics, which have important meaning for crystallography. In this case, delta (Oi), which is a difference between initial oxygen concentration and the other oxygen concentration after heat treatment, increases abruptly in the areas B and C where BMD of high density is easily formed. Having such BMD of high density, the areas B and C may have defects such as vacancy clusters under crystal growth conditions due to thermal history accompanied by crystal growth. Thus, the crystal has to be grown with crystal growth conditions in order to avoid formation of defects related to vacancy clusters in the areas B and C.

A crystal growth method that removes grown-in defects is an ideal technique for growing an ideal silicon crystal containing no grown-in defect in a manner that an OiSF ring is completely removed by being shrunken in the central direction of the crystal growth axis and such that defects related to interstitial clusters such as Large Dislocation Particles (LDP) are excluded. Unfortunately, such methods have technical difficulties including the inability to accelerate the crystal pulling speed to contract the OiSF ring so that the cost of producing a single crystalline silicon ingot is increased greatly.

Thus, instead of contracting an OiSF ring, other methods report that an inner region of the OiSF ring is best removed by being moved from an axis center of crystal growth to the circumference and that grown-in defects are removed through predetermined heat treatment, thereby forming BMD of high density as well as preventing the technical difficulties and the increase of product cost associated with shrinking the OiSF ring in the central direction. However, instead of forming areas B and C where delta (Oi) increases abruptly by moving the OiSF ring toward the circumference, the above method simply forms area A throughout a wafer and removes the grown-in defects by applying predetermined heat treatment. Thus, a wafer having BMD of high density can not be achieved with this method.

As semiconductor devices are highly integrated, it is essential to form a layer free of agglomerated point defect by removing crystal defects and metal impurities from a surface of a wafer, which is an active layer where devices will be formed, produced by the Cz method. For this purpose, numerous studies have been developed to form defect-free layer as follows.

First, a crystal free of agglomerated point defect is grown at the stage of crystal growth. While this method enables the removal of grown-in defects, i.e. Crystal Originated Particle (COP), generated during crystal growth, but fails to form BMD of high density to remove heavy metal impurity during the fabrication of semiconductor devices. This method also incurs a high cost in wafer production due to technical difficulty in increasing growth speed of single crystalline silicon.

Second, Rapid Thermal Annealing (hereinafter abbreviated RTA) is carried out on a silicon wafer produced by arbitrary conditions for crystal growth. This second method enables the removal of grown-in defects generated during crystal growth by RTA and the generation of nuclei for forming BMD of high density to a predetermined thickness from a wafer surface. However, this method using RTA of high temperature results in slip dislocation due to thermal damage, with the slip dislocation causing serious damage to device operation. When RTA of high temperature is carried out for a short time, e.g., less than 60 seconds, this method fails to completely eliminate grown-in defects formed in an active area of a device during crystal growth.

Third, an active layer of a perfect device is secured by growing a silicon epitaxial layer on a silicon wafer produced by arbitrary process conditions. However, this method increases wafer product cost due to the additional step of growing the epitaxial layer, has difficulty associated with the need for an additional step to remove defects such as metal impurity and the like, and has to stabilize the quality of the epitaxial layer.

With regard to heat treatment methods, at least two major methods of heat treatment are known. First, grown-in defects are eliminated by heat treatment at a hydrogen ambience at a high temperature of about 1200° C. using a vertical diffusion furnace. Second, grown-in defects are eliminated by heat treatment at a nitrogen or argon ambience at a high temperature of about 1250° C. using a RTA apparatus.

The first method for removing grown-in defects is effective but fails to form BMD of high density. Particularly, when heat treatment is carried out at a pure hydrogen ambience, a step-type terrace structure is generated on a surface of the wafer. Although it is not clear how such surface characteristics influence device characteristics, it is believed that macro-roughness rather than micro-roughness is affected by the surface characteristics.

The second method enables BMD of high density to be easily formed, but generates slip dislocation due to thermal damage during heat treatment at a high temperature of over 1000° C. undertaken for RTA's sake. Additionally, the process has difficulties such as warp, bow of a wafer and the like, and frequently undergoes mechanical damage at a frictional point between a sample support and a sample. The second method also fails to remove the grown-in defects completely due to the short process time of less than a hundred seconds, thereby leaving some of the grown-in defects in an active layer of a device.

### SUMMARY OF THE INVENTION

Accordingly, the present invention is directed to a method of treating a semiconductor wafer, and a semiconductor wafer fabricated by the methods, that substantially obviates one or more of the problems due to limitations and disadvantages of the related art.

The object of the present invention is to provide a method of producing a wafer which prevents thermal damage due to a thermal treatment of high temperature and eliminates grown-in defects completely.

Another object of the invention is to provide a high quality wafer free of grown-in defects influencing semiconductor device yield, and process impurities, with BMD existing in an active layer of a device.

Additional features and advantages of the invention will be set forth in the description, which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the present invention is directed to a method of treating a wafer thermally, and removing defects contained in single crystalline semiconductor. The method includes the steps of carrying out a first heat treatment on the wafer at a temperature equal to or higher than 1200° C., and carrying out a second heat treatment on the wafer at a temperature equal to or lower than 800° C.

In another aspect, the present invention is directed to a method of producing a semiconductor wafer which includes the steps of producing a single crystalline semiconductor ingot by removing an OiSF ring by means of moving the OiSF ring from a center of a single crystalline semiconductor growth axis to a circumference and by extending a first area and a second area in which delta (Oi) as oxygen concentration difference between initial oxygen concentration and oxygen concentration after heat treatment in N₂ ambience at 1000° C. for 64 hours, is more greatly increased than other areas. The method further includes the steps of providing a wafer by slicing the single crystalline semiconductor ingot, carrying out a first heat treatment on the wafer at a temperature equal to or higher than 1200° C., and carrying out a second heat treatment on the wafer by rapid thermal annealing at a temperature equal to or lower than 800° C.

In another aspect, a semiconductor wafer which is fabricated from a single crystalline semiconductor of the present invention is characterized in that the wafer is produced from a single crystalline semiconductor ingot which is formed by removing an OiSF ring by means of moving the OiSF ring from a center of a single crystalline semiconductor growth axis to a circumference and by extending a first area and a second area in which delta (Oi), as oxygen concentration difference between initial oxygen concentration and oxygen concentration after heat treatment in N₂ ambience at 1000° C. for 64 hours, is more greatly increased than other areas; that grown-in defects are removed from the wafer by heat treatment; that bulk micro-defects are formed in the wafer; and that a defect-free layer is formed from a surface of the wafer to a predetermined depth.

In a further aspect, an epitaxial semiconductor wafer of the present invention is characterized in that the wafer is produced from a single crystalline semiconductor ingot which is formed by removing an OiSF ring by means of moving the OiSF ring from a center of a single crystalline semiconductor growth axis to a circumference and by extending a first area and a second area in which delta (Oi), as oxygen concentration difference between initial oxygen concentration and oxygen concentration after heat treatment in N₂ ambience at 1000° C. for 64 hours, is more greatly increased than other areas; that grown-in defects are removed from the wafer by heat treatment; that bulk micro-defects are formed in the wafer; that a defect-free layer is formed from a surface of the wafer to a predetermined depth; and that an epitaxial layer is formed on an upper surface of the wafer.

In a further aspect, the present invention is directed to a method of growing an ingot which includes the steps of accelerating a speed of growing from a melt-down silicon to a single crystalline silicon ingot, maintaining a temperature gradient distribution from a central part to a circumferential part of the ingot at a growing interface between the melt-down silicon and the ingot grown by crystallization, forming an OiSF ring at the circumferential part or removing the OiSF ring by moving the OiSF ring from a center of a single crystalline semiconductor growth axis to a circumference, and extending an area in which delta (Oi) is greatly increased by being compared to that of other areas, wherein the delta (Oi) is a difference between an initial oxygen concentration and oxygen concentration after heat treatment with a predetermined thermal history.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 shows an XRT image of a vertically-cut single crystalline ingot which is treated thermally at a high temperature of about 1000° C. for 64 hours at an ambience of N₂ under arbitrary conditions of crystal growth;

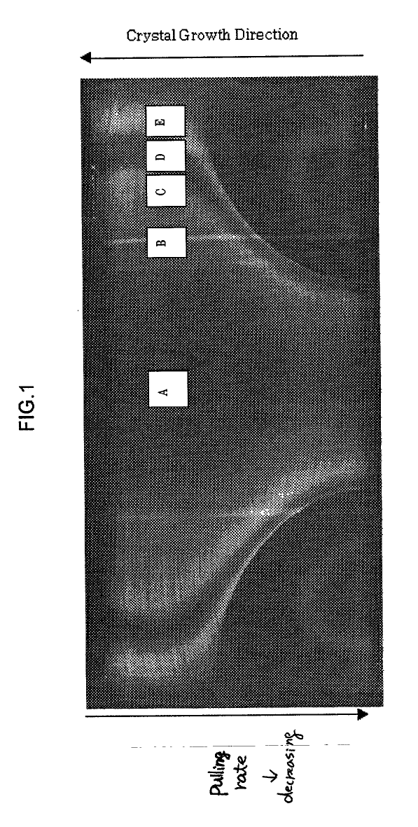

FIG. 2 is a result of oxygen concentration difference observed in a radial direction of a wafer through FTIR spectrometer; and

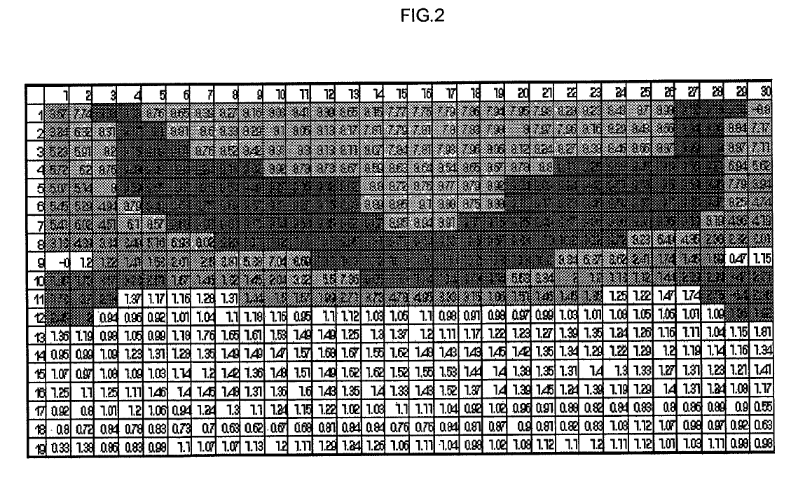

FIG. 3 shows a cross-sectional view of a silicon wafer according to the present invention.

### DETAILED DESCRIPTION OF PREFERRED EMBODIMENTS

Reference will now be made in detail to the preferred embodiments of the present invention, examples of which are illustrated in the accompanying drawings.

The present invention is directed to a method of producing an ingot by removing an OiSF ring completely from a center of a single crystal growth axis to a circumference during single crystalline growth and extending areas B and C, by carrying out a first thermal treatment on a wafer fabricated from the ingot at high temperature, and by carrying out a second thermal treatment of RTA at low temperature.

In order to fabricate a wafer of high quality, the present invention enables the removal of problem-causing grown-in defects, while providing BMD density to improve gettering ability.

Various bands generated from grown-in defects during crystal growth and precipitation of oxygen are mainly the result of thermal history which depends greatly on a thermal hot zone of a crystal growth furnace. Namely, the various bands due to the grown-in defects and oxygen precipitation depend on the temperature gradient around a growing interface between a melt-down silicon and a silicon ingot during crystal growth and cooling condition of the ingot produced by crystal growth.

In accordance with the following steps, the present invention removes an OiSF ring completely from a center of a single crystal growth axis to a circumference during single crystalline growth and extends areas B and C for forming BMD of high density with ease, thereby forming a single crystalline silicon.

First, the cooling rate of an ingot grown by crystallization is accelerated by cutting off heat which is conducted from the melt-down silicon to the crystallizing ingot. In addition, the distribution of temperature gradient around a growing interface between the melt-down silicon and the crystallizing ingot is kept uniform from the center to the circumference of the ingot. By accelerating the growing speed of an ingot, the OiSF ring is extended to be located at a circumference, or removed entirely by being pushed back from the center of a single crystalline growth axis to the circumference. The OiSF ring is removed by means of being moved from a center of a single crystalline semiconductor growth axis to a circumference and by extending area B and area C of which delta (Oi), as oxygen concentration difference between initial oxygen concentration and oxygen concentration after heat treatment in N₂ ambience at 1000° C. for 64 hours, is more greatly increased than other areas. In this case, the areas B and C are formed to be 20 to 90% of an ingot diameter.

Once the OiSF ring is extended to be located at a circumference or removed by being pushed back from the center of a single crystalline growth axis to the circumference, grown-in defects such as COP are very small. The silicon ingot is then fabricated such that areas B and C are extended to 20-90% diameter of a wafer and have no defect related to vacancy clusters but micro defects, wherein BMD of high density is easily formed in the areas B and C. Then, the ingot is sliced to fabricate a wafer.

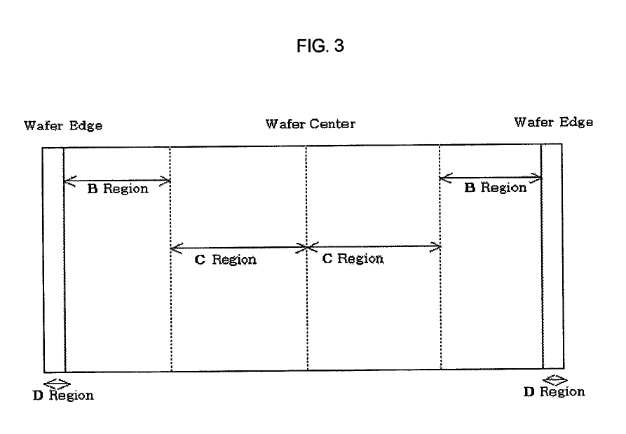

FIG. 3 shows a cross-sectional view of a silicon wafer which is formed by cutting an ingot grown by the above method according to the present invention, wherein an OiSF ring exists on a circumferential part of a wafer as area D, and areas B and C are extended to cover all of the wafer except the circumference.

In order to form a defect-free layer, where electronic circuit devices will be formed on the wafer, fabricated by the above method to have grown-in defects and metal impurities removed simultaneously therefrom, the grown-in defects are completely removed by a vertical diffusion furnace process and low temperature RTA, and a BMD layer is formed to the predetermined thickness of the wafer to enforce gettering ability, which is explained in the following description in detail.

A wafer is thermally treated for 20 minutes to 3 hours at a high temperature of over 1200° C., which is called a first heat treatment step. The ambience of the first heat treatment step is one of hydrogen gas, inert gas, mixed gas of hydrogen and inert gas, and mixed gas of oxygen and inert gas. The flow of inert gas ranges from 2 to 50 slm, while that of mixed gas also ranges from 2 slm to 50 slm. The rate of temperature increase to a thermal treatment process temperature is between 5 and 100° C./min. The rate of cooling after the first heat treatment step ranges between 5 and 100° C./min.

The wafer, which was subjected to the first heat treatment step, is thermally treated at a temperature equal to or lower than about 800° C. by low temperature RTA; this is called the second heat treatment step. The ambience of the second heat treatment step is one of nitrogen gas, hydrogen gas, mixed gas of nitrogen and inert gas, and mixed gas of hydrogen and inert gas. It is preferable to execute the second heat treatment step for a time equal to or less than 2 minutes.

After the first and second heat treatment steps, the grown-in defects are removed from an active area of the wafer and BMD of high density is formed at a predetermined depth from a wafer surface to eliminate metal impurities, thereby securing a defect-free layer from the surface of the wafer to a predetermined depth.

Then, a wafer for semiconductor devices is provided by growing an epitaxial layer 1 to 20 μm thick on the wafer having a defect-free layer thereon. The epitaxial layer formed 1 to 20 μm thick on the wafer on which the defect-free layer is secured is suitable for use as a wafer for semiconductor devices. It is desirable that the first heat treatment explained above be carried out on the epitaxial semiconductor wafer for 20 minutes to 3 hours and the second heat treatment explained above be carried out on the wafer by RTA for a time equal to or less than 2 minutes.

Accordingly, the present invention enables grown-in defects to be nearly or completely eliminated to extend the areas B and C by downsizing grown-in defects such as COP by means of drawing out an OiSF ring from the center of a single crystal growth axis to a circumference thereof and by carrying out thermal treatment on a wafer fabricated from an ingot having no defect related to vacancy cluster inside, but having micro-defects. The present invention also enables a defect-free layer to be formed on a surface of a wafer by removing metal impurity by means of forming BMD of high density through RTA on the wafer fabricated from an ingot in which areas B and C are extended, thereby providing a wafer in which grown-in defects and metal impurity are removed simultaneously.

Moreover, the method of carrying out heat treatment on a semiconductor wafer according to the present invention enables slip dislocation to be prevented by carrying out low temperature RTA below 800° C.

It will be apparent to those skilled in the art that various modifications and variations can be made in a method of treating a semiconductor wafer thermally and a semiconductor wafer fabricated by the same of the present invention without departing from the spirit or scope of the invention. Thus, it is intended that the present invention cover the modifications and variations of this invention provided they come within the scope of the appended claims and their equivalents.

What is claimed is:

1. A method of treating a wafer thermally to remove defects contained in single crystalline semiconductor, the method comprising the steps of:
carrying out a first heat treatment on the wafer at a temperature equal to or higher than 1200° C.; and
carrying out a second heat treatment on the wafer at a temperature equal to or lower than 800° C.

2. The method of treating a wafer thermally according to claim 1, wherein the first heat treatment is carried out for a time period ranging from 20 minutes to 3 hours.

3. The method of treating a wafer thermally according to claim 1, wherein the first heat treatment is carried out at an ambience of one of hydrogen, inert gas, a first mixed gas of hydrogen and inert gas, and a second mixed gas of oxygen and inert gas.

4. The method of treating a wafer thermally according to claim 3, wherein flow of the inert gas, the first mixed gas, and the second mixed gas ranges from 2 to 50 slm.

5. The method of treating a wafer thermally according to claim 1, wherein a rate of temperature increase in the first heat treatment is from 5 to 100° C./min. and a rate of cooling after the first heat treatment is from 5 to 100° C./min.

6. The method of treating a wafer thermally according to claim 1, wherein the second heat treatment is carried out for 2 minutes or less.

7. The method of treating a wafer thermally according to one of claim 1, wherein the wafer is made of silicon.

8. A method of producing a semiconductor wafer, comprising the steps of:
producing a single crystalline semiconductor ingot by removing an OiSF ring by means of moving the OiSF ring from a center of a single crystalline semiconductor growth axis to a circumference and by extending a first area and a second area in which delta (Oi) as oxygen concentration difference between initial oxygen concentration and oxygen concentration after heat treatment in N₂ ambience at 1000° C. for 64 hours, is more greatly increased than other areas;
providing a wafer by slicing the single crystalline semiconductor ingot;
carrying out a first heat treatment on the wafer at a temperature equal to or higher than 1200° C.; and
carrying out a second heat treatment on the wafer by rapid thermal annealing at a temperature equal to or lower than 800° C.

9. A semiconductor wafer which is fabricated from a single crystalline semiconductor,
wherein the wafer is produced from a single crystalline semiconductor ingot which is formed by removing an OiSF ring by means of moving the OiSF ring from a center of a single crystalline semiconductor growth axis to a circumference and by extending a first area and a second area in which delta (Oi), as oxygen concentration difference between initial oxygen concentration and oxygen concentration after heat treatment in N₂ ambience at 1000° C. for 64 hours, is more greatly increased than other areas, wherein grown-in defects are removed from the wafer by heat treatment, wherein bulk micro-defects are formed in the wafer, and wherein a defect-free layer is formed from a surface of the wafer to a predetermined depth.

10. The semiconductor wafer according to claim 9, wherein the first area and the second area in which delta (Oi) is greatly increased is extended to 20 to 90% of a wafer diameter.

11. The semiconductor wafer according to claim 9, wherein the defect-free layer is formed to a thickness of 10 to 100 μm from the surface.

12. The semiconductor wafer according to claim 9, wherein a first heat treatment is carried out on the wafer at a temperature equal to or higher than 1200° C. and subsequently a second heat treatment is carried out on the wafer by rapid thermal annealing at a temperature equal to or lower than 800° C.

13. The semiconductor wafer according to claim 9, wherein the semiconductor wafer is a silicon wafer.

14. An epitaxial semiconductor wafer,
wherein the wafer is produced from a single crystalline semiconductor ingot which is formed by removing an OiSF ring by means of moving the OiSF ring from a center of a single crystalline semiconductor growth axis to a circumference and by extending a first area and a second area in which delta (Oi) as oxygen concentration difference between initial oxygen concentration and oxygen concentration after heat treatment in N₂ ambience at 1000° C. for 64 hours, is more greatly increased than other areas, wherein grown-in defects are removed from the wafer by heat treatment, wherein bulk micro-defects are formed in the wafer, wherein a defect-free layer is formed from a surface of the wafer to a predetermined depth, and wherein an epitaxial layer is formed on an upper surface of the wafer.

15. The epitaxial semiconductor wafer according to claim 14, wherein the epitaxial layer is formed 1 to 20 μm thick.

16. The epitaxial semiconductor wafer according to claim 14, wherein a first heat treatment is carried out on the epitaxial semiconductor wafer for 20 minutes to 3 hours and a second heat treatment is carried out on the wafer by rapid thermal annealing for a time equal to or less than 2 minutes.

17. A method of growing an ingot, comprising the steps of:
accelerating a speed of growing from a melt-down silicon to a single crystalline silicon ingot;
maintaining a temperature gradient distribution from a central part to a circumferential part of the ingot at a growing interface between the melt-down silicon and the ingot grown by crystallization;
forming an OiSF ring at the circumferential part by moving the OiSF ring from a center of a single crystalline semiconductor growth axis to a circumference; and
extending an area in which delta (Oi) is greatly increased as compared to that of other areas, wherein the delta (Oi) is a difference between an initial oxygen concentration and oxygen concentration after heat treatment with a predetermined thermal history.

18. The method of growing an ingot according to claim 17, wherein the heat treatment with the predetermined thermal history is carried out at 1000° C. for 64 hours in a N₂ ambience.

19. The method of growing an ingot according to claim 17, wherein the area in which delta (Oi) is greatly increased is formed to occupy 20 to 90% of a diameter of the ingot.
